(19) United States
(12) Patent Application Publication
(10) Pub. No.: US 2026/0303071 A1
(43) Pub. Date: Oct. 1, 2026

(54) DIGITALLY CONTROLLED OSCILLATOR BIASING AT MINIMUM FREQUENCY

(71) Applicant: QUALCOMM Incorporated, San Diego, CA (US)

(72) Inventors: Sungmin OCK, San Diego, CA (US); John ABCARIUS, San Diego, CA (US); Qingjin DU, San Diego, CA (US)

(21) Appl. No.: 19/089,777

(22) Filed: Mar. 25, 2025

(51) Int. Cl. H03K 3/03; H03K 3/011; H03K 17/687

(52) U.S. Cl. CPC H03K 3/0315; H03K 3/011; H03K 17/6872

(57) ABSTRACT

A clock generation circuit has a ring oscillator configured to receive a bias current from a current source; and a proportional-to-absolute temperature (PTAT) current generation circuit configured to contribute an additional current to the bias current; and a source degeneration circuit comprising diode-connected transistors coupled to a source of a transistor in the PTAT current generation circuit. The diode-connected transistors may be coupled in parallel with a source degeneration resistor in the source degeneration circuit. The diode-connected transistors may be implemented using transistors of the same type as transistors in the ring oscillator. The diode-connected transistors may be included in a circuit that mimics an inverter circuit in the ring oscillator or may be coupled with one another in a parallel configuration. The diode-connected transistors may include a combination of P-type metal-oxide-semiconductor transistors and N-type metal-oxide-semiconductor transistors.

### TECHNICAL FIELD

The present disclosure relates generally to a clock generation circuits and, more particularly, to nonlinear compensation for digitally-controlled oscillator circuits.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever and improvements in process technology have been adopted to implement underlying processing and communication circuits.

In one example, mobile radio frequency integrated circuits (RFICs) may be implemented using deep sub-micron process nodes to reduce cost and power consumption. Mobile RF transceivers, for example, can include many subcircuits to support basic radio frequency (RF) communication functions and enhanced communication features needed to support evolving communication standards and protocols, and to satisfy end-user requirements.

Phase locked loop (PLLs) may be used in integrated circuit (IC) devices to generate an output signal with a phase related to a phase of an input signal. A PLL may be characterized as a closed-loop frequency control system that responds to feedback in the form of a phase difference. The PLL may include a phase frequency detector (PFD), a charge pump, a loop filter, a variable oscillator, and one or more counters. In one example, a PLL may respond to phase differences detected between an input clock signal and a clock signal generated by variable oscillator. The linearity of the relationship between output clock frequency and control voltages may be affected variations in manufacturing process, voltage and/or temperature (PVT), which can affect the operation of transistors and other components in IC devices. There is an ongoing need to improve the design of PLLs and other clock generation circuits as process nodes and/or IC device geometry decrease in size and when increases in RFIC complexity requires comparable increases in PLL functionality, performance and reliability.

### SUMMARY

Certain aspects of the disclosure relate to integrated circuit (IC) devices that includes a clock generation circuit. The clock generation circuit may be adapted or configured to automatically accommodate variances in process, voltage and/or temperature that can affect the operation of transistors in a digitally-controlled oscillator (DCO). The DCO may use an oscillator such as a ring oscillator to generate a clock signal with a desired frequency of oscillation.

In various aspects of the disclosure, the clock generation circuit has a ring oscillator configured to receive a bias current from a current source and a proportional-to-absolute temperature (PTAT) and a source degeneration circuit. The PTAT current generation circuit may be configured to contribute an additional current to the bias current. The source degeneration circuit may include diode-connected transistors coupled to a source of a transistor in the PTAT current generation circuit.

In various aspects of the disclosure, a method for generating clock signals includes providing a bias current to a ring oscillator, contributing a PTAT current to the bias current and contributing a nonlinear temperature-dependent current to the PTAT current using a source degeneration circuit that includes transistors of the same type as transistors in the ring oscillator.

In various aspects of the disclosure, an apparatus includes means for providing a bias current to a ring oscillator, means for contributing a PTAT current to the bias current and means for contributing a nonlinear temperature-dependent current to the bias current.

In certain aspects, the diode-connected transistors are coupled in parallel with a source degeneration resistor in the source degeneration circuit. The diode-connected transistors may be implemented using transistors of the same type as transistors in the ring oscillator. The diode-connected transistors may be included in a circuit that mimics an inverter circuit in the ring oscillator. In some examples, the diode-connected transistors include a combination of P-type metal-oxide-semiconductor (PMOS) transistors and N-type metal-oxide-semiconductor (NMOS) transistors coupled with one another in a parallel configuration.

In one aspect, the source degeneration circuit is coupled to a source of a transistor in a current mirror. In one aspect, a current digital-to-analog converter may be configured to supply the bias current. In one aspect, a voltage regulation circuit may be configured to control a voltage at which the bias current is supplied to the ring oscillator.

### BRIEF DESCRIPTION OF THE DRAWINGS

FIG. 1 illustrates an example of a system-on-a-chip in accordance with certain aspects of the present disclosure.

FIG. 2 illustrates an apparatus employing interconnected chiplets.

FIG. 3 illustrates an example of an apparatus in which chiplets are stacked vertically on a substrate.

FIG. 4 illustrates an example of a phase locked loop that may be adapted according to certain aspects disclosed herein.

FIG. 5 illustrates an example of a digitally-controlled oscillator (DCO) that is based on a ring oscillator.

FIG. 6 illustrates the relationship between current and voltage and between frequency and voltage in the DCO illustrated in FIG. 5.

FIG. 7 illustrates effects of PVT variations on the DCO illustrated in FIG. 5.

FIG. 8 illustrates an example of a DCO, which includes a temperature-compensated current generation circuit that may be adapted or configured in accordance with certain aspects of this disclosure.

FIG. 9 illustrates certain aspects of the relationship between diode-connected transistors and inverters in a ring oscillator.

FIG. 10 illustrates a first example of a temperature-compensated DCO that may be implemented, adapted or configured in accordance with certain aspects of this disclosure.

FIG. 11 illustrates a second example of a temperature-compensated DCO that may be implemented, adapted or configured in accordance with certain aspects of this disclosure.

FIG. 12 is a flowchart of a method for generating clock signals in accordance with certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

Data communication links employed by system-on-a-chip (SoC) and other integrated circuit (IC) devices to connect processors with modems and other peripherals may be operated in accordance with industry or proprietary standards or protocols associated with certain functions or types of devices. According to certain aspects of the disclosure, a serial data link may be used to interconnect electronic devices that are subcomponents of an apparatus such as a cellular phone, a smart phone, a session initiation protocol (SIP) phone, a laptop, a notebook, a netbook, a smartbook, a personal digital assistant (PDA), a satellite radio, a global positioning system (GPS) device, a smart home device, intelligent lighting, a multimedia device, a video device, a digital audio player (e.g., MP3 player), a camera, a game console, an entertainment device, a vehicle component, a wearable computing device (e.g., a smart watch, a health or fitness tracker, eyewear, etc.), an appliance, a sensor, a security device, a vending machine, a smart meter, a drone, a multicopter, or any other similar functioning device.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain examples of circuits are illustrated herein as being implemented using P-type metal-oxide-semiconductor (PMOS) transistors, N-type metal-oxide-semiconductor (NMOS) transistors or some combination of NMOS and PMOS transistors. These circuits are provided by way of example only, and it is contemplated that the concepts disclosed herein can be implemented in circuits that use various other combinations of NMOS and PMOS transistors.

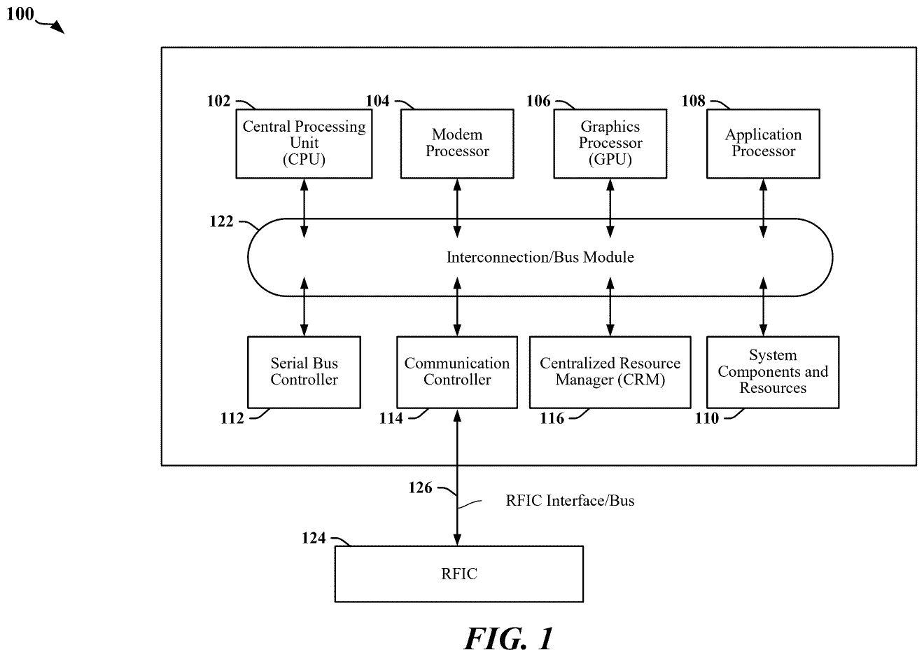

FIG. 1 illustrates an example of an apparatus 100 in which certain components and interconnections can be implemented in an SoC. The apparatus 100 may include a number of heterogeneous processors, such as a central processing unit (the CPU 102), a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., power/voltage rails), as well as for more coordinated cooperation between cores.

The apparatus 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The apparatus 100 may further include a serial bus controller 112 such as a Universal Serial Bus (USB) controller, a communication controller 114, and a centralized resource manager (CRM) 116. The apparatus 100 may also include an input/output module (not illustrated) for communicating with resources external to the SoC, each of which may be shared by two or more of the internal SoC components.

The processors 102, 104, 106, 108 may be interconnected to the serial bus controller 112, the communication controller 114, system components and resources 110, CRM 116, and/or other system components via an interconnection/bus module 122, which may include an array of reconfigurable logic gates and/or implement a bus architecture. Communications may also be provided by advanced interconnects, such as high-performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The communication controller 114 may be a specialized hardware module configured to manage and/or prioritize the flow of data to and from a radio frequency integrated circuit (RFIC) 124 via one or more RFIC communication links 126.

The communication controller 114 may include one or more processors configured to perform operations with the RFIC 124, often within time constraints specified or required by communication standards and protocols. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the RFIC 124 may be part of the apparatus 100.

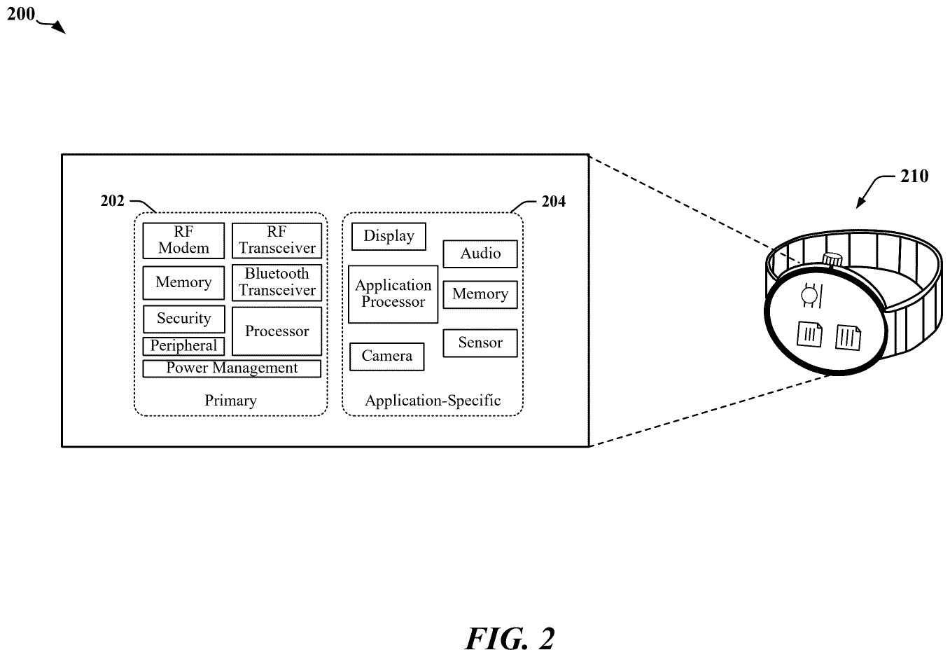

FIG. 2 illustrates an example of an apparatus 200 in which certain components are implemented using multiple chiplets that are interconnected using one or more data communication buses. In one example, the apparatus 200 may be enclosed within a wearable device a portable or wearable processing and/or communication device (each of which being referred to herein as a portable communication device or PCD), sensors, instruments, appliances and other such devices include one or more ICs. These devices may include mobile phones, tablet computers, palmtop computers, portable digital assistants (PDAs), portable game consoles, and other portable electronic devices such as the illustrated smartwatch 210. PCDs commonly contain integrated circuits or SoCs that include numerous components or subsystems designed to work together to deliver functionality to a user. The various SoC subsystems may communicate with each other via one or more intra-chip data buses or similar data communication interconnects. PCDs may have multiple SoCs that communicate with each other via similar inter-chip interconnects. The ICs are typically packaged in an IC package, which may be referred to as a “semiconductor package” or “chip package.” The IC package typically includes a package substrate and one or more IC chips or other electronic modules mounted to the package substrate to provide electrical connectivity to the IC chips. For example, an IC chip in an IC package may be configured as an SoC. The IC chips are electrically coupled to other IC chips and/or to other components in the IC package through electrical coupling to metal lines in the package substrate. The IC chips can also be electrically coupled to other circuits outside the IC package through electrical connections of external metal interconnects (e.g., solder bumps) of the IC package.

Chiplet technology can be used to address some of the performance, power and size design requirements for complex SoCs used in certain mobile or wearable devices. The block diagram in FIG. 2 illustrates certain aspects of an apparatus 200 that can be constructed using chiplets. The apparatus 200 may be configured by selecting a combination of chiplets that implement certain subsystems or distinct functional elements. In the illustrated example, the apparatus 200 includes a set of primary chiplets 202 that enable the apparatus 200 to perform core processing, security and communication functions. The set of primary chiplets 202 include a processor, memory and one or more modems. The illustrated apparatus 200 also includes a set of application-specific chiplets 204 that includes an application processor, display driver, camera interface and audio controller. In a remote sensing device or appliance, the audio-visual components could be omitted and may be replaced with analog-to-digital controllers, for example.

The apparatus 200 may include a variety of processing engines, such as central processing units (CPUs) with multiple cores, graphical processing units (GPUs), digital signal processors (DSPs), neural processing units (NPUs), wireless transceiver units (also referred to as modems), peripherals, display and imaging interfaces, etc. Each of these subsystems and other functional elements can be implemented as an individual chiplet, or as a combination of chiplets. The chiplets included in the apparatus 200 can be proprietary or may be acquired from a variety of sources. An SoC may be constructed from chiplets manufactured at different process nodes and/or operated at different voltages.

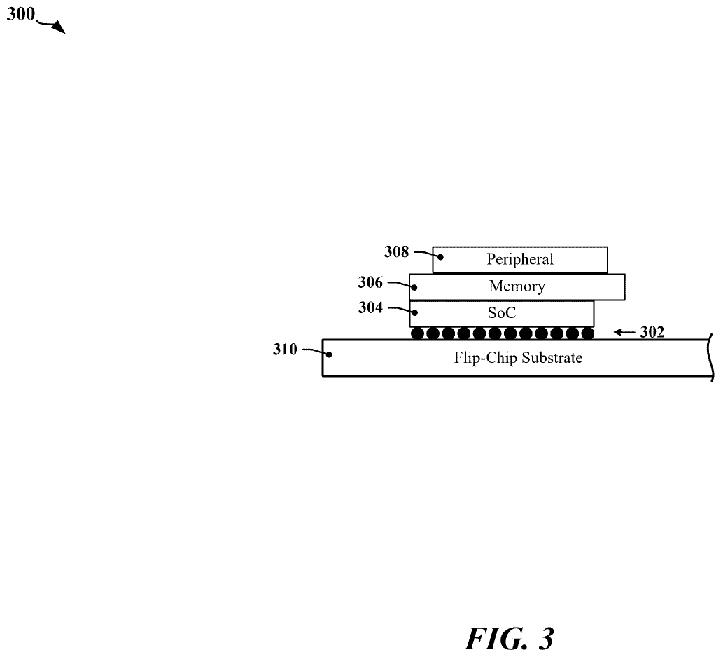

FIG. 3 illustrates an example of an SoC 300 in which certain chiplets 304, 306, 308 are stacked vertically on a substrate 310. Some chiplets can be included in stacks that are deployed across the surface of the substrate 310, while other chiplets may be individually mounted on the surface of the substrate. Chiplets may be mounted on the surface of the substrate using solder balls 302 that provide electrical and/or thermal coupling between substrate and the mounted chiplets. An interconnect structure may be formed that enables chiplets 304, 306, 308 in a stack of chiplets to communicate with one another, with other chiplets mounted on the substrate 310 and with input/output structures that connect the apparatus 200 with other circuits, displays, imaging sensors and other peripherals with an apparatus.

The use of chiplets can reduce the areal size of the substrate 310 and increase three-dimensional packing density. The constituent chiplets may provide complex features and high performance within a smaller form-factor operated at lower power specifications. Moreover, each chiplet may define multiple power domains, operate at different frequencies and different chiplets may manage power/frequency modes independently and. In some instances, two or more chiplets may be operated in mutually exclusive power states. Additionally, operating conditions for an SoC depend on the type, number and arrangement of chiplets included on the substrate in addition to the modes of operation defined by applications. It is necessary to consider power usage by all chiplets in the SoC in order to ensure compliance with power budgets assigned for an application or device.

Conventional chiplet-based implementations suffer from limitations that include complex or difficult interconnect routing, local hotspots arising from routing congestion caused by connection architecture and challenges to signal timing specifications. In certain examples, local hotspots can arise from routing congestion, increased feature complexity and circuit concentrations. In certain examples, signal timing specifications can be compromised due to the necessity for an increased number of isolation clamps due to logic placement, number of voltage domains and reduced floorplan. Long wire crossings between chiplets can cause routing congestion.

Each chiplet in an SoC may be included to perform a specific function or type of function and the configuration of the chiplets can introduce further complexities and challenges for designers. For example, one chiplet may include radio frequency front end circuits that produce high frequency signals ranging up to 5 GHz or more, and may further include interfaces that are used by low-frequency power management circuits. A designer may import previously defined circuit blocks to implement some of the internal functions. These circuit blocks may be referred to as macros. Imported circuit blocks for a given process technology may be described, characterized or defined by a set of masks, hardware description language, specifications and test data. Commercially available or proprietary circuit blocks may be referred to as hard macros. Hard macros are tested and verified for a set of design and operating specifications. It is common for hard macros and other circuit blocks to define multiple power domains.

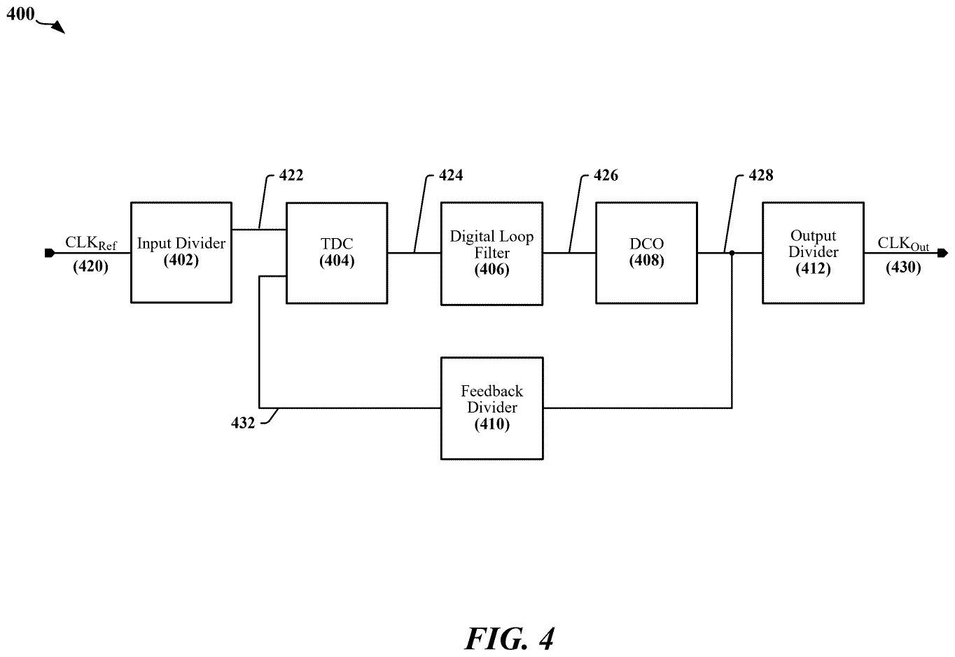

FIG. 4 illustrates an example of a phase locked loop (PLL 400) that may be adapted according to certain aspects disclosed herein. The PLL 400 includes multiple counters configured to operate as frequency divider circuits 402, 410, 412, a Time-to-Digital converter (the TDC 404) which serves as a phase detection circuit, a loop filter 406 (e.g., low pass filter) and a digitally-controlled oscillator (the DCO 408). The PLL 400 may receive a reference clock signal (the CLK_{Ref} signal 420) at a first frequency and provide an output signal (the CLK_{Out} signal 430) at a second frequency, that can be different from the frequency of the CLK_{Ref} signal 420. In some implementations, the CLK_{Ref} signal 420 is derived from a local oscillator circuit, which may comprise a crystal oscillator. In one example, the crystal oscillator may generate the CLK_{Ref} signal 420 at a frequency of tens of megahertz (MHz), while the DCO 408 may be configured to generate a periodic signal in the gigahertz (GHz) range. An input divider circuit 402 may frequency-divide the CLK_{Ref} signal 420 to provide an internal reference signal 422 to the TDC 404.

The DCO 408 may output an intermediate clock signal 428 at a frequency that is different from the frequencies of the CLK_{Ref} signal 420, the internal reference signal 422 and/or the CLK_{Out} signal 430. An output divider circuit 412 may be configured to generate the CLK_{Out} signal 430 by frequency-dividing the intermediate clock signal 428. A feedback divider circuit 410 may frequency-divide the intermediate clock signal 428 to provide a reduced-frequency feedback signal 432 to the TDC 404. The frequency of the internal reference signal 422 and the reduced-frequency feedback signal 432 may be matched when the PLL accomplishes a locked mode of operation. The TDC 404 may cooperate with the digital loop filter 406 to control the phase and or frequency of the intermediate clock signal 428 generated by the DCO 408. In the illustrated example, an output signal 424 of the TDC 404 is received by the digital loop filter 406 which may be configured to respond to output signal 424 by adjusting the value of a control word encoded in a control signal 426 provided to the DCO 408. The control signal 426 can configure the frequency of the intermediate clock signal 428 generated by the DCO 408. The TDC 404 may cause the DCO 408 to configure the intermediate clock signal 428 such that it replicates and tracks the internal reference signal 422.

In some implementations, the DCO 408 may be replaced by a voltage-controlled oscillator (VCO), or the like to replicate and track the internal reference signal 422. A voltage-controlled oscillator responds to a voltage level provided to its control input. In some implementations, the DCO 408 may be implemented using oscillators relying on resonant circuits that employ a combination of inductance (L) and capacitance (C) (i.e., LC-based oscillators). Certain concepts described in relation to ring oscillators herein apply equally to LC-based oscillators.

In many implementations, the DCO 408 performs a critical role in a high-frequency digital PLL. The DCO 408 is the source of high-frequency clock signals used by various sub-systems in an IC device, including by the CPU 102 (see FIG. 1). The linearity, precision and consistency of the high-frequency clock signals provided by a PLL can be affected by improvements in process technology which tend to result in scaled down feature sizes of devices in an IC. Enhanced capabilities of systems that include the IC may demand an increased operational frequency range of the DCO 408, and such demands can impose greater challenges on the oscillator design process.

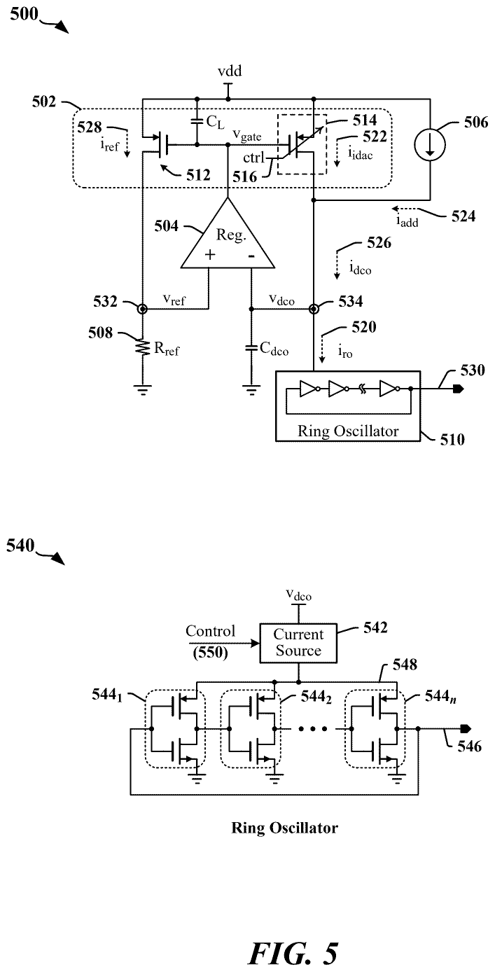

FIG. 5 illustrates an example of a DCO 500 that is based on a ring oscillator 510. FIG. 5 also illustrates one example of a ring oscillator 540. In certain implementations, the ring oscillator 540 includes an odd number of inverting stages 544₁-544ₙ connected in a loop. In other implementations, the ring oscillator 540 can include an even number of inverting stages 544₁-544ₙ connected in a loop. The quantity (n) of the inverting stages 544₁-544ₙ may be selected to create conditions for stable oscillation. In a stabilized mode of operation, the gain around the loop is equal to unity and the accumulated phase shift is equal to an integer multiple of 360°. In one example, each of the inverting stages 544₁-544ₙ connected in the loop includes an inverter configured with an input driven by a preceding inverting stage 544₁-544ₙ and an output that drives a next inverting stage 544₁-544ₙ. In the illustrated example, inverting stage 544ₙ can be considered to precede inverting stage 544₁ in the loop.

The ring oscillator 540 generates an output signal 546 that is a function of the process corners associated with one or more devices in the ring oscillator 540. For an odd number of inverting stages 544₁-544ₙ, the delay (τ) introduced by each of the inverting stages 544₁-544ₙ defines the free-running oscillation frequency (f₀) of the output signal 546. In the illustrated example, f₀=(2πτ)⁻¹, with phase difference between stages=360°/n. The value of τ and the corresponding f₀ may be defined by controlling the bias current provided to the inverting stages 544₁-544ₙ of the ring oscillator 540. In the illustrated example, the bias current is provided to the inverting stages 544₁-544ₙ by a current source 542 that is coupled to a power rail 548 of the ring oscillator 540. The current source 542 may be implemented using a current digital-to-analog converter (IDAC) that is configured by a control signal 550. In one example, the control signal 550 is a multibit signal that encodes a multibit codeword. The current source 542 outputs a current that has an amplitude defined by the control signal 550.

The DCO 500 illustrated in FIG. 5 includes a ring oscillator 510 that may correspond in certain respects to the ring oscillator 540. For example, the ring oscillator 510 may include an odd number of inverters connected in a loop, where the delay introduced by each of the inverting stages is configured by the magnitude of a current (iᵣₒ 520) provided to the ring oscillator 510. In a stabilized mode of operation, a consistent level of iᵣₒ 520 is provided to the ring oscillator 510. The amplitude of iᵣₒ 520 may be calculated as the sum of amplitudes of a current (i_{idac} 522) produced by an IDAC 514 and an additional current (i_{add} 524) that may be provided as an additional bias current to ensure reliable oscillation of the ring oscillator 510.

In the illustrated example, the IDAC 514 is implemented using parallel-connected transistors. The number of active transistors in the parallel connected transistors may be defined by an IDAC control signal 516. In one example, the IDAC control signal 516 is a multibit signal that encodes a multibit control codeword. The control codeword may be used to activate certain transistors. An active transistor may be enabled or turned on using a switch controlled by the control codeword. The control codeword may be encoded using binary or unary encoding. Binary encoding may be used to specify a numerical quantity of active parallel connected transistors in the IDAC 514 to be enabled. Unary encoding, which may be referred to as thermometer encoding, represents data in the quantity of bits set to binary ‘1’ that precede a terminating binary ‘0’, or the quantity of bits set to binary ‘O’ that precede a terminating binary ‘1’. Thus, in one embodiment, the magnitude of the current produced by the IDAC 514 is controlled using thermometer coding in which bit values set to binary ‘1’ cause at least one corresponding transistor to be turned on.

Each enabled transistor in the illustrated IDAC 514 contributes a unit of current to i_{idac} 522. In the illustrated example, a current mirror 502 is configured to reproduce a reference current (i_{iref} 528) in each enabled transistor in the illustrated IDAC 514 such that:

$${i}_{idac} = N \times {i}_{ref} ,$$

where N is the number of enabled, parallel connected transistors in the IDAC 514. The reference current flows through a reference transistor 512 and a reference resistor 508, producing a reference voltage (V_{ref}) at a reference node 532. The reference node 532 that couples the reference transistor 512 to the reference resistor 508. In some implementations, the reference resistor 508 may be replaced by a current source that can be configured to generate a unit current.

The reference node 532 is further coupled to an input of a voltage regulator amplifier 504. The sources of the enabled transistors in the IDAC 514 are coupled to a VDD power rail. Current flows to the ring oscillator 510 through the drains of the enabled transistors in the IDAC 514 and through a DCO node 534. Another input of the voltage regulator amplifier 504 is coupled to the DCO node 534. The voltage regulator amplifier 504 produces an output that is proportional to the difference between V_{ref} and the voltage (V_{dco}) at the DCO node 534 and operates to cause the voltage at the DCO node 534 to follow the voltage at the reference node 532. When V_{ref}=V_{dco}:

$${i}_{idac} = N \times {i}_{ref} = N \times \frac{{V}_{ref}}{{R}_{ref}} = N \times \frac{{V}_{dco}}{{R}_{ref}} .$$

In the illustrated example, a current source 506 provides the additional current (i_{add} 524) through the DCO node 534. In some implementations, the current source 506 is programmable such that i_{add} 524 is provided at a desired magnitude to produce a combined current (i_{dco} 526) that may be calculated as:

$${i}_{idco} = N \times \frac{{V}_{dco}}{{R}_{ref}} + {i}_{add} .$$

The current (iᵣₒ 520) provided to the ring oscillator 510 and the frequency of the output signal 530 generated by the ring oscillator 510 change nonlinearly with changes in V_{dco}. When V_{dco} has a small enough voltage, the ring oscillator 510 does not oscillate, and a very small iᵣₒ 520 flows to the ring oscillator 510. When the voltage of V_{dco} increases above a threshold voltage level, the ring oscillator 510 will begin oscillating and both frequency of the output signal 530 and the magnitude of iᵣₒ 520 can be expected to increase rapidly with V_{dco}.

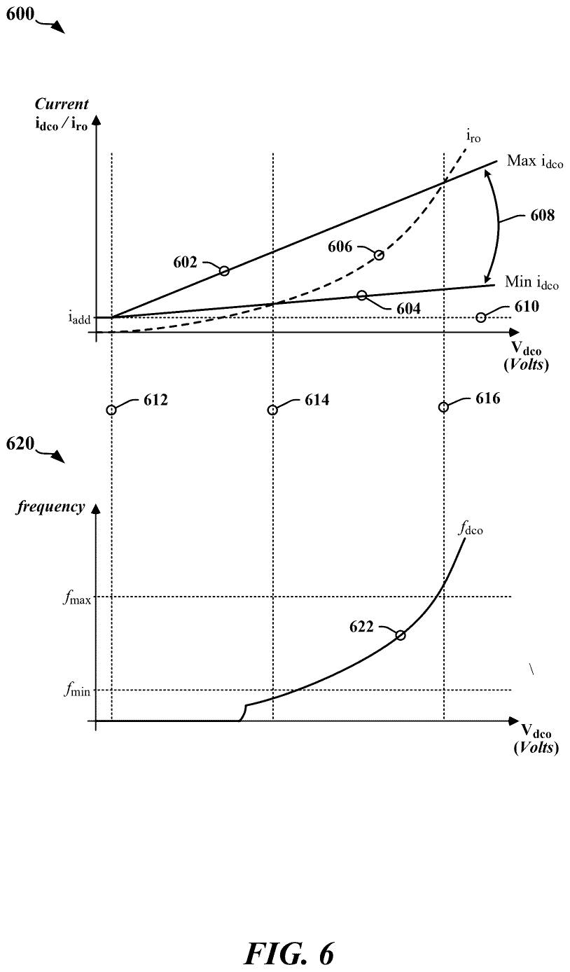

FIG. 6 includes graphs 600, 620 that illustrate the relationship between current and voltage and between frequency and voltage in the DCO 500 illustrated in FIG. 5. The feedback loop provided in the DCO 500 may be configured to settle the amplitude of V_{dco} in order to match iᵣₒ 520 (i.e., the ring oscillator current) and the i_{dco} 526 current. The amplitude of iᵣₒ 520 may be increased to obtain increased oscillator frequency, and the frequency of the output signal 530 generated by the ring oscillator 510. In the illustrated example, a certain number of transistors in the IDAC 514 may be enabled in order to provide an iᵣₒ 520 with an amplitude that configures a delay (τ) that is introduced by each of inverting stage in the ring oscillator 510. The sum of the delays in the ring oscillator 510 correspond to the period of the output signal 530 and defines the free-running oscillation frequency of the ring oscillator 510.

The first graph 600 plots iᵣₒ 520 and i_{dco} 526 current for a range of V_{dco} voltage levels. Increasing V_{dco} voltage level produces a linear increase in i_{dco} 526 current for a fixed number of enabled transistors in the IDAC 514. In the first graph 600, a first characteristic 602 corresponds to a maximum number of enabled transistors and a second characteristic 604 corresponds to a minimum number of enabled transistors. The number of enabled transistors may vary within a range 608 that can be used to define a maximum and minimum frequency that is required of, or that can be configured for the output signal 530. At lower V_{dco} voltage levels, the proportionate contribution of i_{add} 524 to i_{dco} 526 increases and, at V_{dco} voltage levels below a threshold voltage level 610, i_{dco} 526 is negligible or disabled such that only i_{add} 524 can enable continued oscillation of the ring oscillator 510.

With continued reference to the first graph 600, the curve 606 for iᵣₒ 520 is non-linear in the depicted range of V_{dco} voltage levels. The non-linear relationship derives in part from the alternating current (AC) flow caused by switching within the ring oscillator 510. The AC current consumed by the ring oscillator 510 increases nonlinearly with oscillation frequency of the ring oscillator 510. Oscillation frequency of the ring oscillator 510 increases with V_{dco} voltage level.

The second graph 620 includes a curve 622 that plots oscillation frequency (f_{dco}) for the range of V_{dco} voltage levels. Oscillation may be stalled in the ring oscillator 510 until the magnitude of iᵣₒ 520 reaches a minimum level at a corresponding minimum V_{dco} voltage level 614. At lower V_{dco} voltage levels, no i_{dco} 526 current flow is provided and only i_{add} 524 contributes to iᵣₒ 520. At a certain voltage level 612, i_{dco} 526, current flow has commenced but may be insufficient to cause the ring oscillator 510 to oscillate. At some voltage levels, the ring oscillator 510 oscillates but stability is not expected until the specified minimum voltage level 614 is reached.

At the specified minimum voltage level 614, the frequency of the output signal 530 may be less than the minimum specified frequency defined for the DCO 500. Design specifications may require that the frequency of the output signal 530 at the specified minimum voltage level 614 is less than the minimum specified frequency defined for the DCO 500 for all expected PVT variances. At a specified maximum voltage level 616, the frequency of the output signal 530 may be exceed the maximum specified frequency defined for the DCO 500. Design specifications may require that the frequency of the output signal 530 at the specified maximum voltage level 616 is greater than the maximum specified frequency defined for the DCO 500 for all expected PVT variances.

Developments in process technology are often associated with scaled down device sizes which can affect the ability of the DCO 500 and its associated ring oscillator 510 to accommodate PVT variations, including variations in temperatures affecting transistor operation, for example. The use of smaller device sizes may enable the DCO 500 to achieve higher maximum frequencies. On the other hand, a ring oscillator 510 constructed using reduced-geometry, fast devices may be subject to substantially increased PVT variations when V_{dco} voltage is low, and the ring oscillator 510 may be unable to meet requirements for minimum specified frequencies or otherwise perform as specified over all expected PVT corners. PVT corners may refer to operating points, parameters and/or conditions that are defined by manufacturing tolerances (process corners) and by different voltage or temperature limits defined for circuits included in the ring oscillator 510.

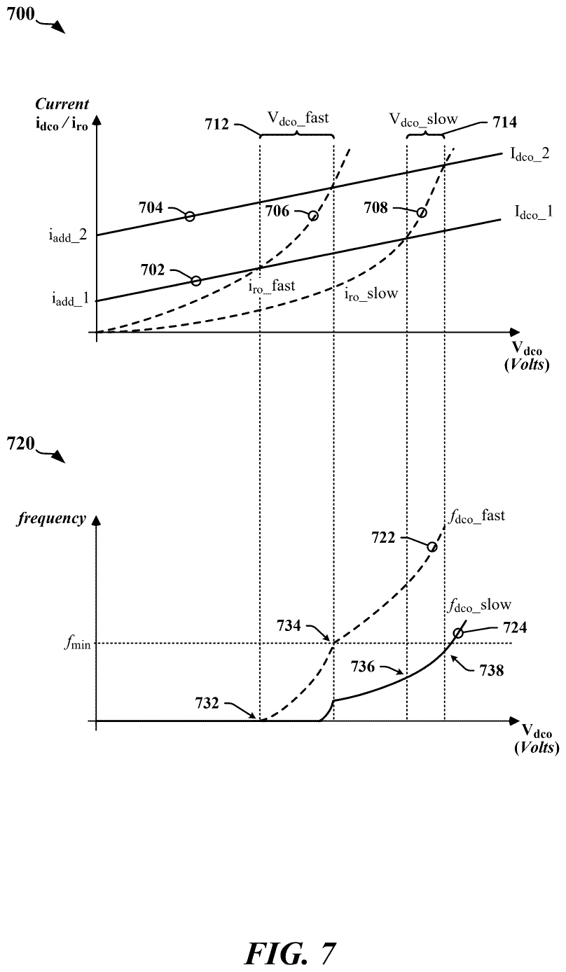

FIG. 7 includes graphs 700, 720 that illustrate certain effects of PVT variations on the DCO 500 illustrated in FIG. 5. The graphs 700, 720 illustrate characteristics of the DCO 500 when a minimum number of transistors in the IDAC 514 are enabled. The first graph 700 includes two straight-line characteristics 702, 704 that plot i_{dco} 526 current over different ranges 712, 714 of V_{dco} voltage levels for different levels of i_{add} 524 current. A first range 712 of V_{dco} voltage levels corresponds to a PVT corner in which temperature is elevated and transistor switching speeds are relatively fast. A second range 714 of V_{dco} voltage levels corresponds to a PVT corner in which temperature is normal or low and transistor switching speeds are relatively slow. The first graph 700 further includes curves 706, 708. The first RO curve 706 plots iᵣₒ 520 over the first range 712 of V_{dco} voltage levels for the PVT corner in which temperature is elevated and the second RO curve 708 plots iᵣₒ 520 over the second range 712 of V_{dco} voltage levels for the PVT corner in which temperature is normal or low. The second graph 720 includes curves 722, 724 that plot frequency of oscillation against V_{dco} voltage level for two different PVT corners.

The slope of the straight-line characteristics 702, 704 is moderate or slightly inclined with respect to a characteristic related to a maximum number of enabled transistors in the IDAC 514. The V_{dco} voltage levels are also low in the illustrated straight-line characteristics 702, 704. In these current ranges, the contribution of i_{add} 524 current may be needed to maintain a minimum V_{dco} voltage level across the ring oscillator 510 required to achieve the minimum frequency defined for the DCO 500. PVT variations can have amplified effect for near-minimum V_{dco} voltage levels. The effects of temperature variations on iᵣₒ 520 and V_{dco} levels can render the DCO 500 unreliable or inoperative at minimum frequency.

Adjustments made to the i_{add} 524 current may resolve certain issues at one or more PVT corners, but may compromise performance at other PVT corners. For example, maintaining a low current level for i_{add} 524, as shown by straight-line characteristic 702, may enable the DCO 500 to generate the output signal 530 with a frequency that is less than the minimum frequency specified for the DCO 500 in low-temperature, slow transistor switching PVT corners, but may suppress or produce marginal oscillation of the ring oscillator 510 in high-temperature, fast transistor switching PVT corners. Oscillation may be suppressed or unreliable when the voltage level of V_{dco} is insufficient to enable switching of the inverters in the ring oscillator 510.

Maintaining a higher current level for i_{add} 524, as shown by straight-line characteristic 704, may enable the DCO 500 to generate an oscillating output signal 530 for all PVT corners, but may prevent the DCO 500 from generating an output signal 530 with a frequency that is lower than the minimum frequency specified for the DCO 500 in high-temperature, fast transistor switching PVT corners. The second graph 720 shows the operating point 732 at a high-temperature, fast transistor switching PVT corner for the low i_{add} current level corresponding to the straight-line characteristic 702 and the operating point 734 at the high-temperature, fast transistor switching PVT corner for the higher i_{add} current level corresponding to the straight-line characteristic 704. The second graph 720 also shows the operating point 736 at a low-temperature, slow transistor switching PVT corner for the low i_{add} current level corresponding to the straight-line characteristic 702 and the operating point 738 at the low-temperature, slow transistor switching PVT corner for the higher i_{add} current level corresponding to the straight-line characteristic 704.

It can be challenging or impracticable to configure i_{add} 524 such that the DCO 500 can generate an output signal 530 and achieve the minimum frequency of oscillation specified for the DCO 500 over all expected PVT conditions. It may be necessary to employ a current source that can accommodate variances in operating temperature of the DCO 500 generally and, more particularly, variances in temperature of the transistors used in the ring oscillator 510. A primary origin of the temperature dependence of i_{add} 524 is the effect of temperature on mobility of charge carriers and increased leakage within the ring oscillator 510.

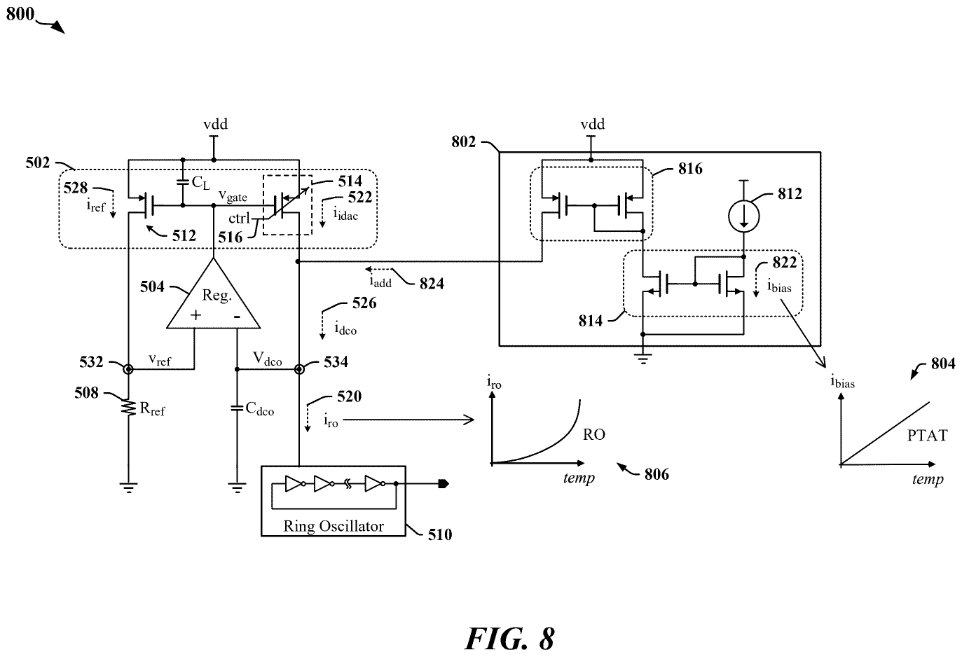

FIG. 8 illustrates an example of a DCO 800 that includes a temperature-compensated current generation circuit 802. The DCO 800 corresponds in many respects to the DCO 500 illustrated in FIG. 5 and fundamental modes of operation are similar. The temperature-compensated current generation circuit 802 can be configured to produce a current flow (i_{add} 824) that may be provided as an additional bias current to ensure oscillation of the ring oscillator 510.

The illustrated temperature-compensated current generation circuit 802 operates as a proportional-to-absolute temperature (PTAT) current source that contributes an additional temperature-dependent current to i_{dco} 526. In one aspect, a PTAT current source can be configured to contribute an additional temperature-dependent current to the bias current flowing through one or more transistors in the ring oscillator 510. The temperature-compensated current generation circuit 802 includes two current mirrors 814, 816 that may be configured to control a temperature coefficient and current magnitude. Temperature variations affecting the transistors in the ring oscillator 510 can be expected to also affect the transistors in the current mirrors 814, 816. The temperature coefficient determines the relationship between current and temperature for the current mirrors 814, 816, and an example of such relationship is illustrated in the PTAT graph 804. The current (i_{bias} 822) flowing to the first current mirror 814 is generated by a current source 812 and is replicated through the current mirrors 814, 816 such that i_{add} 824 follows i_{bias} 822. Accordingly, temperature-induced variations in i_{bias} 822 are reflected in i_{add} 824.

The use of the temperature-compensated current generation circuit 802 can compensate for variations in iᵣₒ 520. Compensation is obtained through the summing of i_{add} 824 with i_{dco} 526. However, the compensation provided by the temperature-compensated current generation circuit 802 is imperfect. As illustrated by the RO graph 806, temperature-related variations in iᵣₒ 520 are typically non-linear, whereas temperature-related variations in i_{add} 824 can be expected to be substantially linear, resulting in continued non-linear variation in iᵣₒ 520.

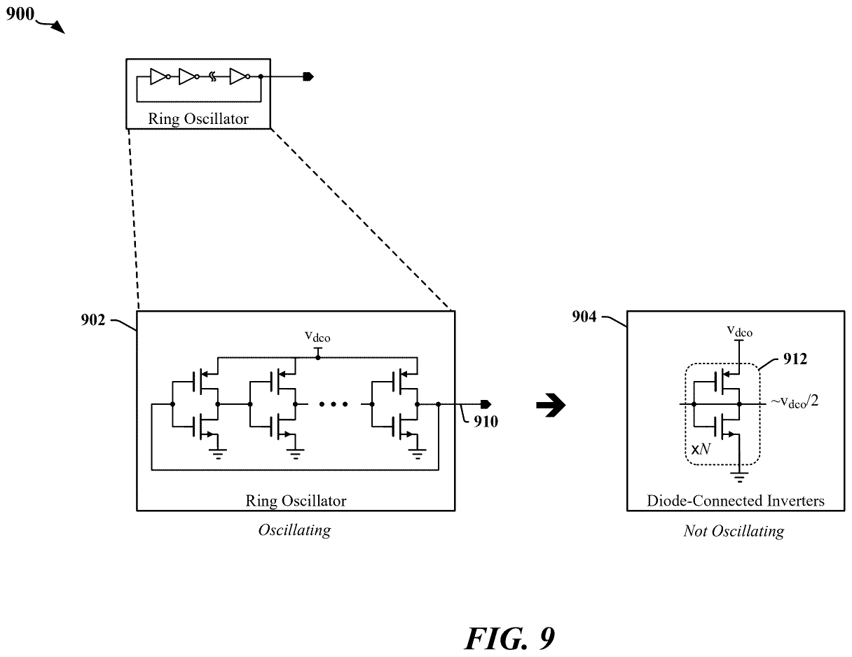

The non-linear variations in iᵣₒ 520 may be caused in part by leakage within the ring oscillator 510. Certain aspects of this disclosure can compensate for non-linear variations in the ring oscillator current 510. In some implementations, diode-connected transistors may be used to contribute a temperature-variable current to the ring oscillator current. FIG. 9 illustrates certain aspects of the relationship between diode-connected transistors and the inverters in a ring oscillator 900. An example of a ring oscillator 902 is implemented using a combination of P-type metal-oxide-semiconductor (PMOS) transistors and N-type metal-oxide-semiconductor (NMOS) transistors. The circuits depicted herein are provided by way of example only, and it is contemplated that the concepts disclosed herein can be implemented in circuits that use different combinations of NMOS and PMOS transistors.

The ring oscillator 902 generates an output signal 910 using an odd number (N) of inverting stages that receive power through a power rail that has a variable voltage (V_{dco}). The ring oscillator 902 may not oscillate when the voltage level V_{dco} is lower than a threshold minimum level. All inverter inputs and outputs tend to settle near the V_{dco}/2 voltage level when the ring oscillator 902 is not oscillating. The ring oscillator 902 effectively becomes a load element 904 comprising N load cells, each load cell 912 including one or more diode-connected PMOS transistors coupled to one or more diode-connected NMOS transistors. Certain temperature-compensated current sources implemented in accordance with this disclosure employ a load element that includes diode-connected transistors that are configured based on the load element 904 that results when the ring oscillator 902 is not oscillating. A circuit that uses diode-connected transistors can emulate leakage in the ring oscillator 902 and can be used to provide an additional bias current that exhibits the same or similar non-linear variance when V_{dco} is at low voltage levels.

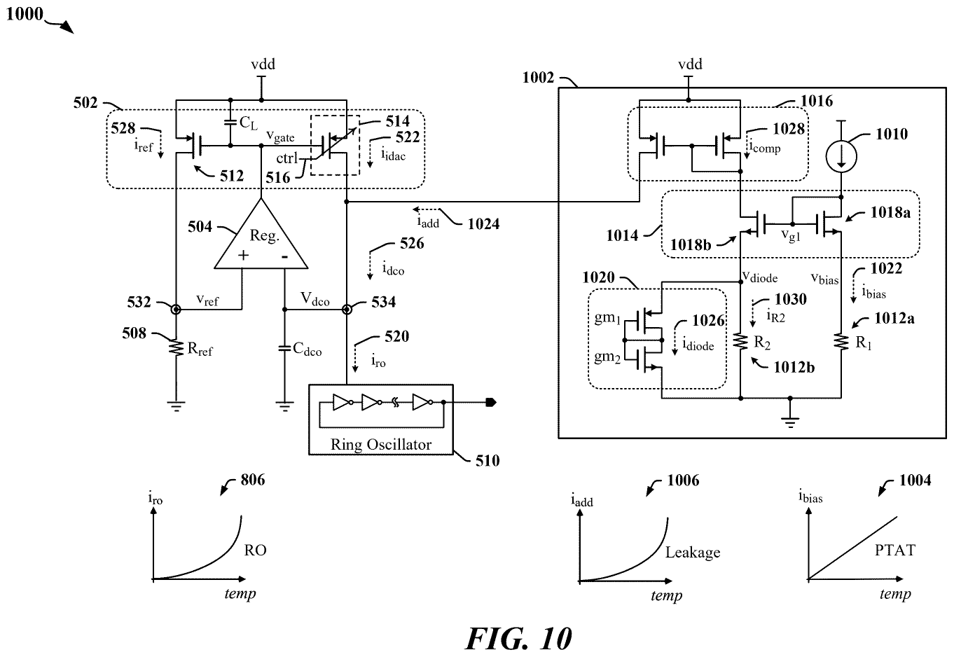

FIG. 10 illustrates a first example of a temperature-compensated DCO 1000 that may be implemented, adapted or configured in accordance with certain aspects of this disclosure. The DCO 1000 corresponds in certain respects to the DCO 500 illustrated in FIG. 5 and the DCO 800 illustrated in FIG. 8. Certain fundamental modes of operation of the DCO 1000 are similar to the modes of operation described herein with respect to the DCO 500.

The DCO 1000 includes a current generation circuit 1002 that may be configured to produce an additional bias current (i_{add} 1024) that can be used to compensate for PVT variations. In one example, i_{add} 1024 may be summed with i_{dco} 526 current to provide iᵣₒ 520 in a stabilized mode of operation. In one aspect, i_{add} 1024 can be configured to ensure oscillation of the ring oscillator 510 at low V_{dco} voltage levels. The illustrated current generation circuit 1002 operates as a PTAT current source and includes a load element 1020 that is implemented using diode-connected transistors. The current generation circuit 1002 includes two current mirrors 1014, 1016 that may be configured to control a temperature coefficient and current magnitude. The current mirrors 1014, 1016 are implemented using transistors of the same type and properties as the transistors in the ring oscillator 510. Temperature variations affecting the transistors in the ring oscillator 510 can be expected to also affect the transistors in the current mirrors 1014, 1016. The temperature coefficient determines the relationship between current and temperature for the current mirrors 1014, 1016. An example of the relationship between current and temperature associated with the current mirrors 1014, 1016 is illustrated in the PTAT graph 1004.

The first current mirror 1014 includes a pair of transistors 1018a, 1018b that have sources coupled to ground through respective source degeneration resistors (R₁ 1012a and R₂ 1012b). A current (i_{bias} 1022) flowing through transistor 1018a of the first current mirror 1014 is generated by a current source 1010 and develops a bias voltage (Vbias) across R₁ 1012a and a diode voltage (V_{diode}) across R₂ 1012b. R₁ 1012a may be configured with a resistance that is calculated to maintain the V_{diode} voltage at the specified minimum V_{dco} voltage level. The drain of transistor 1018a is coupled to the gates of both transistors 1018a, 1018b in the first current mirror 1014 and the source voltage of transistor 1018b follows the source voltage of transistor 1018a. In some implementations, transistor 1018b and R₂ 1012b represent multiple (N) transistor/resistor subcircuits coupled in parallel and, in these implementations, i_{bias} 1022 flows through each subcircuit and i_{add} 1024 is the sum of the currents flowing through the subcircuits. If the load element 1020 is disabled or not present, i_{add} 1024 can be expected to follow i_{bias} 1022. In some implementations, the magnitude of i_{add} 1024 may be greater than the magnitude of i_{bias} 1022. Temperature-induced variations in i_{bias} 1022 may be reflected and/or amplified in i_{add} 1024.

The use of the current generation circuit 1002 as a PTAT current source can compensate for some variations in iᵣₒ 520. Compensation can be achieved through the summing of i_{add} 1024 with i_{dco} 526. However, an i_{add} 1024 generated using PTAT-based compensation can be expected to be substantially linear and may not fully compensate for nonlinear variations in iᵣₒ 520.

According to certain aspects of this disclosure, the load element 1020 may provide non-linear compensation in i_{add} 1024 when included in the current generation circuit 1002. The gate and drain of a diode-connected transistor are coupled together. The load element 1020 can emulate the effects of leakage attributable to transistors in the ring oscillator 510. The illustrated load element 1020 includes diode-connected NMOS and PMOS transistors in a circuit configuration that mimics an inverter circuit or stage in the ring oscillator 902 (see FIG. 9). The structure and relative proportions of the NMOS transistors and PMOS transistors in the load element 1020 may be nearly identical to the structure and relative proportions of the NMOS transistors and PMOS transistors in the ring oscillator 510.

In the illustrated example, the load element 1020 is coupled in parallel with R₂ 1012b and may draw a current (i_{diode} 1026) that includes a leakage component. Increased device temperatures can cause increased leakage in the load element 1020 and can increase i_{diode} 1026. Current can be expected to increase non-linearly with temperature as illustrated in the leakage graph 1006. The relationship between i_{add} 1024 and temperature can be expected to mimic the relationship between iᵣₒ 520 and temperature when the V_{dco} is at low voltage levels.

A degeneration structure coupled to the source of transistor 1018b includes the load element 1020 and R₂ 1012b. Transistors 1018a and 1018b may be implemented using multiple parallel connected subcircuits or slices. In certain implementations, transistor 1018b is implemented using a multiple (N) of the subcircuits or slices used to implement transistor 1018a. In these implementations, the resistor R₂ is also implemented using the parallel connection of a multiple (N) of R₁. The additional current may be calculated as:

$${i}_{add} = {i}_{comp} = {i}_{R 2} + {i}_{diode} ,$$

where:

$${R}_{2} = {R}_{1} / N .$$

The transconductance gain of the transistors in the load element 1020 (represented as gm₁ and gm₂) may be small enough that the magnitude of i_{diode} 1026 is negligible. In these circumstances, the first current mirror 1014 is substantially unaffected by load element 1020 and i_{add} 1024 is controlled by the configuration of the transistors 1018a, 1018b and their respective source degeneration resistors (R₁ 1012a and R₂ 1012b). Here, the source voltage (V_{diode}) of transistor 1018b can be expected to follow the source voltage (Vbias) of transistor 1018a and:

$${i}_{comp} = \frac{{v}_{diode}}{{R}_{2}} = \frac{{v}_{diode}}{{R}_{1} / N} = N \times {i}_{R 1} = N \times {i}_{bias} ,$$

where i_{bias} 1122 is a PTAT current generated by the current generation circuit 1002.

Non-linear increases in transconductance gain attributable to increased temperature and/or process variations can impact the total compensation current (i_{comp} 1028) through changes in load provided by the load element 1020. For example, increases in gm₁ and gm₂ can increase i_{comp} 1028, and thereby increase i_{add} 1024. The total current (i_{comp} 1028) through transistor 1018b can be expressed as V_{diode}/R_{degen}, where R_{degen} is the resistance of the degeneration structure, and which may be expressed as:

$${R}_{degen} = ( ( ( \frac{1}{{gm}_{1}} ) + ( \frac{1}{{gm}_{2}} ) ) // ( \frac{{R}_{1}}{N} ) ) ,$$

In one example, the transconductance gain of a transistor may be calculated as:

$${g}_{m} = \frac{{i}_{drain}}{{v}_{gate - source}} .$$

The values of gm₁ and gm₂ are non-linearly increased with temperature increases. R_{degen} is nonlinearly reduced by temperature. Accordingly, the magnitude of i_{comp} 1028 increases non-linearly with temperature.

The second current mirror 1016 replicates the total compensation current (i_{comp} 1028) flowing through transistor 1018b to produce i_{add} 1024. The total compensation current (i_{comp} 1028) depends on gm₁ and gm₂, and is expected to change when manufacturing process or temperature variations alter the values of gm₁ and gm₂. In one example, increasing device temperature causes the 1/gm₁ and 1/gm₂ terms to decrease nonlinearly, thereby reducing the resistance value of R_{degen}. Decreased resistance increases the magnitude of i_{diode} 1026 and the magnitude of i_{comp} 1028. This temperature-compensated current increase can enable the ring oscillator 510 to achieve a frequency that is lower than the minimum frequency specified for the DCO 1000 over expected PVT conditions.

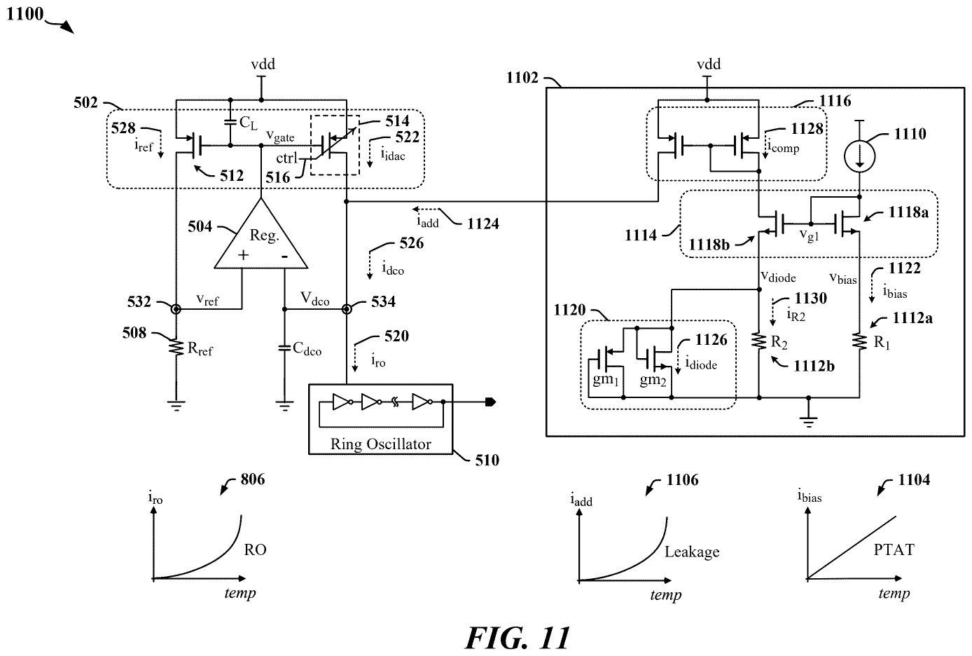

FIG. 11 illustrates a second example of a temperature-compensated DCO 1100 that may be implemented, adapted or configured in accordance with certain aspects of this disclosure. The DCO 1100 corresponds in certain respects to the DCO 500 illustrated in FIG. 5 and the DCO 800 illustrated in FIG. 8. Certain fundamental modes of operation of the DCO 1100 are similar to the modes of operation described herein with respect to the DCO 500.

The DCO 1100 includes a current generation circuit 1102 that may be configured to produce an additional bias current (i_{add} 1124) that can be used to compensate for PVT variations. In one example, i_{add} 1124 may be summed with i_{dco} 526 current to provide iᵣₒ 520. In one aspect, i_{add} 1124 can be configured to ensure oscillation of the ring oscillator 510 at low V_{dco} voltage levels. The illustrated current generation circuit 1102 operates as a PTAT current source and includes a load element 1120 that is implemented using diode-connected transistors. The current generation circuit 1102 includes two current mirrors 1114, 1116 that may be configured to control a temperature coefficient and current magnitude. The current mirrors 1114, 1116 are implemented using transistors of the same type and properties as the transistors in the ring oscillator 510. Temperature variations affecting the transistors in the ring oscillator 510 can be expected to also affect the transistors in the current mirrors 1114, 1116. The temperature coefficient determines the relationship between current and temperature for the current mirrors 1114, 1116. An example of the relationship between current and temperature associated with the current mirrors 1114, 1116 is illustrated in the PTAT graph 1104.

The first current mirror 1114 includes a pair of transistors 1118a, 1118b that have sources coupled to ground through respective source degeneration resistors (R₁ 1112a and R₂ 1112b). A current (i_{bias} 1122) flowing through a transistor 1118a of the first current mirror 1114 is generated by a current source 1110 and develops a bias voltage (Vbias) across R₁ 1112a and a diode voltage (V_{diode}) across R₂ 1112b. The R₁ 1112a resistor may be configured with a resistance that is calculated to maintain the V_{diode} voltage at half the specified minimum V_{dco} voltage level. The drain of transistor 1118a is coupled to the gates of both transistors 1118a, 1118b in the first current mirror 1114 and the source voltage of transistor 1118b follows the source voltage of transistor 1118a. In some implementations, transistor 1118b and R₂ 1112b represent multiple (N) transistor/resistor subcircuits coupled in parallel and, in these implementations, i_{bias} 1122 flows through each subcircuit and i_{add} 1124 is the sum of the currents flowing through the subcircuits. If the load element 1120 is disabled or not present, i_{add} 1124 can be expected to follow i_{bias} 1122. In some implementations the magnitude of i_{add} 1124 may be greater than the magnitude of i_{bias} 1122. Temperature-induced variations in i_{bias} 1122 may be reflected and/or amplified in i_{add} 1124.

The use of the current generation circuit 1102 as a PTAT current source can compensate for some variations in iᵣₒ 520. Compensation can be achieved through the summing of i_{add} 1124 with i_{dco} 526. However, an i_{add} 1124 generated using PTAT-based compensation can be expected to be substantially linear and may not fully compensate for nonlinear variations in iᵣₒ 520.

According to certain aspects of this disclosure, the load element 1120 may provide non-linear compensation in i_{add} 1124 when included in the current generation circuit 1102. The illustrated load element 1120 includes diode-connected NMOS and PMOS transistors. The load element 1120 can emulate the effects of leakage attributable to transistors in the ring oscillator 510. The illustrated load element 1120 includes diode-connected NMOS and PMOS transistors that are coupled in parallel. The structure and relative proportions of NMOS and PMOS transistors in the load element 1020 may be nearly identical to the structure and relative proportions of the NMOS transistors and PMOS transistors in the ring oscillator 510. Coupling the parallel diode-connected NMOS and PMOS transistors in parallel can maximize the voltage headroom available for the load element 1120. For example, the illustrated load element 1120 may be able to operate effectively at lower V_{dco} voltage levels than the load element 1020 illustrated in FIG. 10. In some implementations, R₁ 1112a and R₂ 1112b can be implemented to provide less resistance than the source degeneration resistors 1012a and R₂ 1012b in the DCO 1000 illustrated in FIG. 10.

In the illustrated example, the load element 1120 is coupled in parallel with R₂ 1112b and may draw a current (i_{diode} 1126) that includes a leakage component. Increased device temperatures can cause increased leakage in the load element 1120 and can increase i_{diode} 1126. Current can be expected to increase non-linearly with temperature as illustrated in the leakage graph 1106. The relationship between i_{add} 1124 and temperature can be expected to mimic the relationship between iᵣₒ 520 and temperature when the V_{dco} is at low voltage levels.

A degeneration structure coupled to the source of transistor 1118b includes the load element 1120 and R₂ 1112b. Transistors 1118a and 1118b may be implemented using multiple parallel connected subcircuits or slices. In certain implementations, transistor 1118b is implemented using a multiple (N) of the subcircuits or slices used to implement transistor 1118a. In these implementations, the resistor R₂ is also implemented using the parallel connection of a multiple (N) of R₁. The additional current may be calculated as:

$${i}_{add} = {i}_{comp} = {i}_{R 2} + {i}_{diode} ,$$

where:

$${R}_{2} = {R}_{1} / N .$$

The transconductance gain of the transistors in the load element 1120 (represented as gm₁ and gm₂) may be small enough that the magnitude of i_{diode} 1126 is negligible. In these circumstances, the first current mirror 1114 is substantially unaffected by load element 1120 and i_{add} 1124 is controlled by the configuration of the transistors 1118a, 1118b and their respective source degeneration resistors (R₁ 1112a and R₂ 1112b). Here, the source voltage (V_{diode}) of transistor 1018b can be expected to follow the source voltage (Vbias) of transistor 1118a and:

$${i}_{comp} = \frac{{v}_{diode}}{{R}_{2}} = \frac{{v}_{diode}}{{R}_{1} / N} = N \times {i}_{R 1} = N \times {i}_{bias} ,$$

where i_{bias} 1122 is a PTAT current generated by the current generation circuit 1102.

Non-linear increases in transconductance gain attributable to increased temperature and/or process variations can impact the total compensation current (i_{comp} 1128) through changes in load provided by the load element 1120. For example, increases in gm₁ and gm₂ can increase i_{comp} 1128, and thereby increase i_{add} 1124. The total current (i_{comp} 1128) through transistor 1118b can be expressed as V_{diode}/R_{degen}, where R_{degen} is the resistance of the degeneration structure, and which may be expressed as:

$${R}_{degen} = ( ( \frac{1}{{gm}_{1}} ) // ( \frac{1}{{gm}_{2}} ) ) // ( \frac{{R}_{1}}{N} ) ) ,$$

where gm₁ and gm₂ represent the transconductance gain of the transistors in the load element 1120. The values of gm₁ and gm₂ are non-linearly increased with temperature increases. R_{degen} is nonlinearly reduced by temperature. Accordingly, the magnitude of i_{comp} 1128 increases non-linearly with temperature

The total compensation current (i_{comp} 1128) depends on gm₁ and gm₂, and is expected to change when manufacturing process or temperature variations alter the values of gm₁ and gm₂. In one example, increasing device temperature causes the 1/gm₁ and 1/gm₂ terms to decrease nonlinearly, thereby reducing the resistance value of R_{degen} nonlinearly. Decreased resistance increases the magnitude of i_{diode} 1126 and the magnitude of i_{comp} 1128. This temperature-compensated current increase can enable the ring oscillator 510 to achieve a frequency that is lower than the minimum frequency specified for the DCO 1100 over expected PVT conditions.

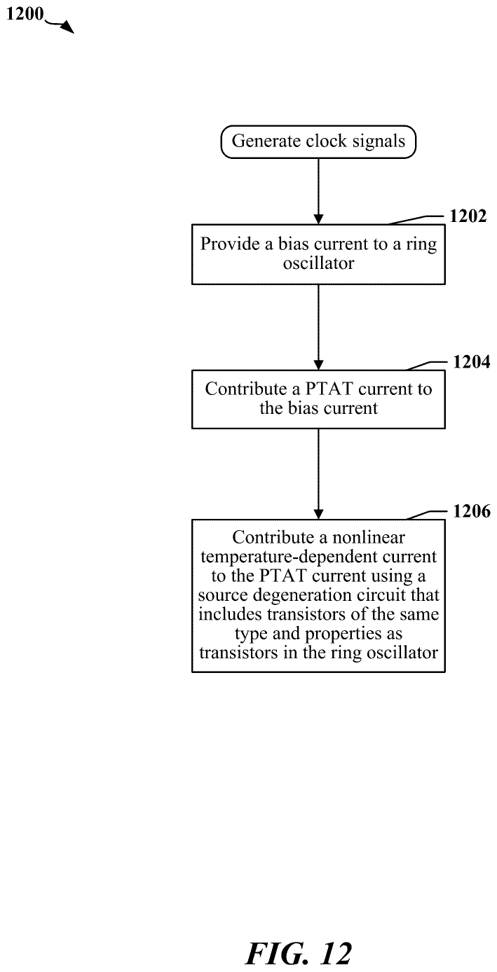

FIG. 12 is a flowchart 1200 of a method for generating clock signals in accordance with certain aspects of this disclosure. At block 1202 in the illustrated method, a bias current may be provided to a ring oscillator. At block 1204 in the illustrated method, a PTAT current may be contributed to the bias current. In one example, the PTAT current may be generated to vary linearly with temperature.

At block 1206 in the illustrated method, a nonlinear temperature-dependent current may be contributed to the PTAT current using a source degeneration circuit. The nonlinear temperature-dependent current may superimpose non-linear variance on the PTAT current by current summing. The source degeneration circuit may include transistors of the same type as transistors used to implement the ring oscillator. The source degeneration circuit may include diode-connected transistors. In some implementations, the diode-connected transistors may be coupled in parallel with a source degeneration resistor in the source degeneration circuit.

In some examples, the source degeneration circuit includes a circuit that mimics an inverter circuit in the ring oscillator. In some examples, the source degeneration circuit comprises a combination of PMOS transistors and NMOS transistors coupled with one another in a parallel configuration.

In some implementations, an IDAC may be used to provide the bias current. A voltage regulator may be used to control voltage at which the bias current is supplied to the ring oscillator.

The method illustrated in FIG. 12 may be performed in an IC device. In one example, the IC device comprises an SoC. In another example, the IC device is included in one of multiple semiconductor dice mounted on a substrate. The IC device may be implemented as a chiplet, in some instances. The IC device may include means for providing a bias current to a ring oscillator, means for contributing a PTAT current to the bias current, and means for contributing a nonlinear temperature-dependent current to the bias current.

In one example, the ring oscillator may be configured to receive a bias current from a current source. The current source may be implemented using an IDAC and voltage regulator. The IDAC may be used to control the magnitude of the bias current. The voltage regulator may be configured to control the voltage level at which the bias current is supplied to the ring oscillator. The IDAC and voltage regulator may be operated cooperatively to configure the frequency of an output of the ring oscillator.

In one example, the PTAT current may be generated by a circuit that includes a current source and current mirrors. A source degeneration circuit may be coupled to a source of a transistor in one of the current mirrors. The source degeneration circuit may include diode-connected transistors that are configured to modify the PTAT current in a nonlinear manner. For example, temperature increases affecting the diode-connected transistors may cause increases in leakage current. The numbers and types of diode-connected transistors may be selected to match or mimic certain characteristics of the ring oscillator. In some instances, the diode-connected transistors may be implemented using transistors of the same type as transistors in the ring oscillator. In some implementations, the diode-connected transistors may be arranged or included in a circuit that mimics a circuit in the ring oscillator. In one example, the circuit may be an inverter circuit. In some implementations, the diode-connected transistors may be arranged or included in a circuit in which different types of transistors are coupled with one another in a parallel configuration. The diode-connected transistors may include some combination of PMOS transistors and NMOS transistors.

Some implementation examples are described in the following numbered clauses:
1. A clock generation circuit, comprising: a ring oscillator configured to receive a bias current from a current source; a proportional-to-absolute temperature (PTAT) current generation circuit configured to contribute an additional current to the bias current; and a source degeneration circuit comprising diode-connected transistors coupled to a source of a transistor in the PTAT current generation circuit.
2. The clock generation circuit as described in clause 1, wherein the diode-connected transistors are coupled in parallel with a source degeneration resistor in the source degeneration circuit.
3. The clock generation circuit as described in clause 1 or clause 2, wherein the diode-connected transistors are implemented using transistors of the same type as transistors in the ring oscillator.
4. The clock generation circuit as described in any of clauses 1-3, wherein the diode-connected transistors are included in a circuit that mimics an inverter circuit in the ring oscillator.
5. The clock generation circuit as described in any of clauses 1-3, wherein the diode-connected transistors comprise a combination of P-type metal-oxide-semiconductor (PMOS) transistors and N-type metal-oxide-semiconductor (NMOS) transistors coupled with one another in a parallel configuration.
6. The clock generation circuit as described in any of clauses 1-5, wherein the source degeneration circuit is coupled to a source of a transistor in a current mirror.
7. The clock generation circuit as described in any of clauses 1-6, further comprising: a current digital-to-analog converter (IDAC) configured to supply the bias current; and a voltage regulation circuit configured to control a voltage at which the bias current is supplied to the ring oscillator.
8. An apparatus, comprising: means for providing a bias current to a ring oscillator; means for contributing a proportional-to-absolute temperature (PTAT) current to the bias current; and means for contributing a nonlinear temperature-dependent current to the bias current.
9. The apparatus as described in clause 8, wherein the means for contributing a nonlinear temperature-dependent current comprises diode-connected transistors coupled to a source of a transistor provided by the means for contributing the PTAT current to the bias current.
10. The apparatus as described in clause 9, wherein the diode-connected transistors are implemented using transistors of the same type as transistors in the ring oscillator.
11. The apparatus as described in clause 9 or clause 10, wherein the diode-connected transistors are included in a circuit that mimics an inverter circuit in the ring oscillator.
12. The apparatus as described in clause 9 or clause 10, wherein the diode-connected transistors comprise a combination of P-type metal-oxide-semiconductor (PMOS) transistors and N-type metal-oxide-semiconductor (NMOS) transistors coupled with one another in a parallel configuration.
13. The apparatus as described in any of clauses 8-12, wherein the diode-connected transistors are coupled to a source of a transistor in a current mirror.
14. The apparatus as described in any of clauses 8-13, wherein the means for providing the bias current to the ring oscillator comprises: a current digital-to-analog converter (IDAC); and means for controlling a voltage at which the bias current is supplied to the ring oscillator.
15. A method for generating clock signals, comprising: providing a bias current to a ring oscillator; contributing a proportional-to-absolute temperature (PTAT) current to the bias current; and contributing a nonlinear temperature-dependent current to the PTAT current using a source degeneration circuit that includes transistors of the same type as transistors in the ring oscillator.
16. The method as described in clause 15, wherein the source degeneration circuit comprises diode-connected transistors.
17. The method as described in clause 16, wherein the diode-connected transistors are coupled in parallel with a source degeneration resistor in the source degeneration circuit.
18. The method as described in any of clauses 15-17, wherein the source degeneration circuit comprises a circuit that mimics an inverter circuit in the ring oscillator.
19. The method as described in any of clauses 15-17, wherein the source degeneration circuit comprises a combination of P-type metal-oxide-semiconductor (PMOS) transistors and N-type metal-oxide-semiconductor (NMOS) transistors coupled with one another in a parallel configuration.
20. The method as described in any of clauses 15-19, further comprising: using a current digital-to-analog converter (IDAC) to provide the bias current; and using a voltage regulator to control voltage at which the bias current is supplied to the ring oscillator.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

1. A clock generation circuit, comprising:
a ring oscillator configured to receive a bias current from a current source;
a proportional-to-absolute temperature (PTAT) current generation circuit configured to contribute an additional current to the bias current; and
a source degeneration circuit comprising diode-connected transistors coupled to a source of a transistor in the PTAT current generation circuit, wherein the diode-connected transistors are implemented using transistors of the same type as transistors in the ring oscillator.

2. The clock generation circuit of claim 1, wherein the diode-connected transistors are coupled in parallel with a source degeneration resistor in the source degeneration circuit.

3. (canceled)

4. The clock generation circuit of claim 1, wherein the diode-connected transistors are included in a circuit that mimics an inverter circuit in the ring oscillator.

5. The clock generation circuit of claim 1, wherein the diode-connected transistors comprise a combination of P-type metal-oxide-semiconductor (PMOS) transistors and N-type metal-oxide-semiconductor (NMOS) transistors coupled with one another in a parallel configuration.

6. The clock generation circuit of claim 1, wherein the source degeneration circuit is coupled to a source of a transistor in a current mirror.

7. The clock generation circuit of claim 1, further comprising:
a current digital-to-analog converter (IDAC) configured to supply the bias current; and
a voltage regulation circuit configured to control a voltage at which the bias current is supplied to the ring oscillator.

8. An apparatus, comprising:
means for providing a bias current to a ring oscillator;
means for contributing a proportional-to-absolute temperature (PTAT) current to the bias current; and
means for contributing a nonlinear temperature-dependent current to the bias current, wherein the means for contributing a nonlinear temperature-dependent current comprises diode-connected transistors that are implemented using transistors of the same type as transistors in the ring oscillator.

9. The apparatus of claim 8, wherein comprises the diode-connected transistors are coupled to a source of a transistor provided by the means for contributing the PTAT current to the bias current.

10. (canceled)

11. The apparatus of claim 9, wherein the diode-connected transistors are included in a circuit that mimics an inverter circuit in the ring oscillator.

12. The apparatus of claim 9, wherein the diode-connected transistors comprise a combination of P-type metal-oxide-semiconductor (PMOS) transistors and N-type metal-oxide-semiconductor (NMOS) transistors coupled with one another in a parallel configuration.

13. The apparatus of claim 9, wherein the diode-connected transistors are coupled to a source of a transistor in a current mirror.

14. The apparatus of claim 8, wherein the means for providing the bias current to the ring oscillator comprises:
a current digital-to-analog converter (IDAC); and
means for controlling a voltage at which the bias current is supplied to the ring oscillator.

15. A method for generating clock signals, comprising:
providing a bias current to a ring oscillator;
contributing a proportional-to-absolute temperature (PTAT) current to the bias current; and
contributing a nonlinear temperature-dependent current to the PTAT current using a source degeneration circuit that includes transistors of the same type as transistors in the ring oscillator, wherein the source degeneration circuit comprises diode-connected transistors of the same type as transistors in the ring oscillator.

16. (canceled)

17. The method of claim 15, wherein the diode-connected transistors are coupled in parallel with a source degeneration resistor in the source degeneration circuit.

18. The method of claim 15, wherein the source degeneration circuit comprises a circuit that mimics an inverter circuit in the ring oscillator.

19. The method of claim 15, wherein the source degeneration circuit comprises a combination of P-type metal-oxide-semiconductor (PMOS) transistors and N-type metal-oxide-semiconductor (NMOS) transistors coupled with one another in a parallel configuration.

20. The method of claim 15, further comprising:
using a current digital-to-analog converter (IDAC) to provide the bias current; and
using a voltage regulator to control voltage at which the bias current is supplied to the ring oscillator.
